(19) United States
(12) Patent Application Publication
(10) Pub. No.: US 2025/0120280 A1
(43) Pub. Date: Apr. 10, 2025

(54) DISPLAY DEVICE

(71) Applicant: Samsung Display Co., LTD., Yongin-si (KR)

(72) Inventor: Hyung Guen YOON, Yongin-si (KR)

(73) Assignee: Samsung Display Co., LTD., Yongin-si (KR)

(21) Appl. No.: 18/889,863

(22) Filed: Sep. 19, 2024

(30) Foreign Application Priority Data
Oct. 4, 2023 (KR) 10-2023-0131647

(51) Int. Cl. H10K 59/38; H10K 59/80; H10K 102/00; H10K 102/10

(52) U.S. Cl. CPC H10K 59/38; H10K 59/873; H10K 59/878; H10K 2102/103; H10K 2102/331; H10K 2102/351

(57) ABSTRACT

A display device includes a reflective layer disposed on a substrate and reflecting light, a color conversion layer disposed on the reflective layer, absorbing light in a first wavelength band, and emitting light in a second wavelength band, a light emitting element layer disposed on the color conversion layer, and emitting the light in the first wavelength band, and a resonant filter disposed on the light emitting element layer, reflecting the light in the first wavelength band, and transmitting the light in the second wavelength band. The resonant filter includes a plurality of semi-transmission layers and at least one medium layer disposed between the semi-transmission layers.

### CROSS-REFERENCE TO RELATED APPLICATION(S)

This application claims priority to and benefits of Korean patent application No. 10-2023-0131647 under 35 U.S.C. § 119(a), filed on Oct. 4, 2023, in the Korean Intellectual Property Office (KIPO), the entire contents of which are incorporated herein by reference.

### BACKGROUND

### 1. Technical Field

The disclosure generally relates to a display device.

### 2. Description of the Related Art

Recently, as interest in information displays is increased, research and development of display devices have been continuously conducted.

### SUMMARY

Embodiments provide a display device having improved reliability.

In accordance with an embodiment of the disclosure, a display device may include a reflective layer disposed on a substrate and reflecting light, a color conversion layer disposed on the reflective layer, absorbing light in a first wavelength band, and emitting light in a second wavelength band, a light emitting element layer disposed on the color conversion layer and emitting the light in the first wavelength band, and a resonant filter disposed on the light emitting element layer, reflecting the light in the first wavelength band, and transmitting the light in the second wavelength band. The resonant filter may include a plurality of semi-transmission layers and at least one medium layer disposed between the plurality of semi-transmission layers.

The resonant filter may include a first semi-transmission layer, a first medium layer, a second semi-transmission layer, a second medium layer, and a third semi-transmission layer, which are sequentially stacked. The first semi-transmission layer, the second semi-transmission layer, and the third semi-transmission layer may include a conductive material. The first medium layer and the second medium layer may include an insulating material.

The first semi-transmission layer, the second semi-transmission layer, and the third semi-transmission layer may include a metal thin film having a thickness less than or equal to about 30 nm. The first medium layer and the second medium layer may include an organic layer or an inorganic layer.

The first semi-transmission layer, the first medium layer, the second semi-transmission layer, the second medium layer, and the third semi-transmission layer may have different thicknesses.

The first medium layer and the second medium layer may have a same thickness.

The first medium layer and the second medium layer may have different thicknesses. One of the first medium layer and the second medium layer may have a thickness which is less than two times of a thickness of another one of the first medium layer and the second medium layer.

The light emitting element layer may include an anode electrode and a light emitting layer. The first semi-transmission layer may be a cathode electrode, the first medium layer may be a capping layer, and the second semi-transmission layer, the second medium layer, and the third semi-transmission layer may be an encapsulation layer.

The resonant filter may have a double Fabry-Perot cavity structure.

The anode electrode may include a transparent conductive material.

The anode electrode may be connected to the reflective layer while penetrating the color conversion layer.

The reflective layer, the color conversion layer, and the light emitting element layer may constitute a pixel. The pixel may include a first sub-pixel, a second sub-pixel, and a third sub-pixel. The resonant filter may be disposed in the first sub-pixel and the second sub-pixel, and may not be disposed in the third sub-pixel.

The first sub-pixel may emit red light in a wavelength band in a range of about 620 nm to about 680 nm, the second sub-pixel may emit green light in a wavelength band in a range of about 520 nm to about 580 nm, and the third sub-pixel may emit blue light in a wavelength band in a range of about 420 nm to about 480 nm.

The resonant filter may reflect about 70% to about 90% of the blue light. The resonant filter may transmit about 40% to about 90% of the red light and the green light.

The light emitting element layer may emit the blue light or celadon light obtained by mixing blue and green. The color conversion layer includes first color conversion particles disposed in the first sub-pixel, absorbing the blue light, and emitting the red light, and second color conversion particles disposed in the second sub-pixel, absorbing the blue light, and emitting the green light.

The color conversion layer may further include light scattering particles disposed in the third sub-pixel.

The display device may further include a color filter layer disposed on the resonant filter. The color filter layer may include a first color filter disposed in the first sub-pixel, a second color filter disposed in the second sub-pixel, and a third color filter disposed in the third sub-pixel.

The resonant filter may include a first semi-transmission layer, a first medium layer, a second semi-transmission layer, a second medium layer, a third semi-transmission layer, and a third medium layer, which are sequentially stacked. The first semi-transmission layer, the second semi-transmission layer, and the third semi-transmission layer may include a conductive material, and the first medium layer, the second medium layer, and the third medium layer may include an insulating material.

The light emitting element layer may include an anode electrode and a light emitting layer. The first semi-transmission layer may be a cathode electrode. The first medium layer and the third medium layer may include an inorganic material, and the second medium layer may include an organic material. The first medium layer, the second medium layer, and the third medium layer may be an encapsulation layer.

In accordance with an embodiment of the disclosure, a display device may include a reflective layer disposed on a substrate and reflecting light, a color conversion layer disposed on the reflective layer, absorbing light in a first wavelength band, and emitting light in a second wavelength band, a light emitting element layer disposed on the color conversion layer and emitting the light in the first wavelength band, and a multi-layer semi-transmission filter disposed on the light emitting element layer, reflecting the light in the first wavelength band, and transmitting the light in the second wavelength band. The multi-layer semi-transmission filter may include at least four pairs of refractive layers, and each of the refractive layers may include a high refractive layer and a low refractive layer, which are sequentially stacked.

The high refractive layer may have a thickness of about 60 nm and a refractive index of about 1.85, and the low refractive layer may have a thickness of about 60 nm and a refractive index of about 1.45.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a plan view schematically illustrating a display device in accordance with embodiments of the disclosure.

FIG. 2 is a schematic diagram of an equivalent circuit of a sub-pixel included in the display device shown in FIG. 1 in accordance with an embodiment of the disclosure.

FIG. 3 is a schematic cross-sectional view of the display device shown in FIG. 1 in accordance with an embodiment of the disclosure.

FIG. 4 is a schematic cross-sectional view illustrating confinement of light in a display panel shown in FIG. 3.

FIG. 5 is a schematic cross-sectional view of a resonant filter included in the display device shown in FIG. 3 in accordance with an embodiment of the disclosure.

FIG. 6 is a schematic cross-sectional view of a resonant filter included in the display device shown in FIG. 3 in accordance with an embodiment of the disclosure.

FIG. 7 is a schematic cross-sectional view of the pixel taken along line I-I′ shown in FIG. 1 in accordance with an embodiment of the disclosure.

FIG. 8 is a schematic cross-sectional view of the pixel taken along line I-I′ shown in FIG. 1 in accordance with an embodiment of the disclosure.

FIG. 9 is a schematic cross-sectional view of the pixel taken along the line I-I′ shown in FIG. 1 in accordance with an embodiment of the disclosure.

FIG. 10 is a schematic cross-sectional view of the pixel taken along the line I-I′ shown in FIG. 1 in accordance with an embodiment of the disclosure.

FIG. 11 is a schematic cross-sectional view illustrating a comparative example of the pixel taken along the line I-I′ shown in FIG. 1.

FIG. 12 is a schematic cross-sectional view illustrating an embodiment of a multi-layer semi-transmission filter.

FIG. 13 is a graph illustrating a reflectance of the multi-layer semi-transmission filter shown in FIG. 12 according to a number of refractive layers included in the multi-layer semi-transmission filter.

### DETAILED DESCRIPTION OF THE EMBODIMENTS

The disclosure may apply various changes and different shape, therefore only illustrate in details with particular examples. However, the examples do not limit to certain shapes but apply to all the change and equivalent material and replacement. The drawings included are illustrated a fashion where the figures are expanded for the better understanding.

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The effects and characteristics of the disclosure and a method of achieving the effects and characteristics will be clear by referring to the embodiments described below in detail together with the accompanying drawings. However, the disclosure is not limited to the embodiments disclosed herein but may be implemented in various forms.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display device in accordance with an embodiment of the disclosure will be described with reference to the accompanying drawings.

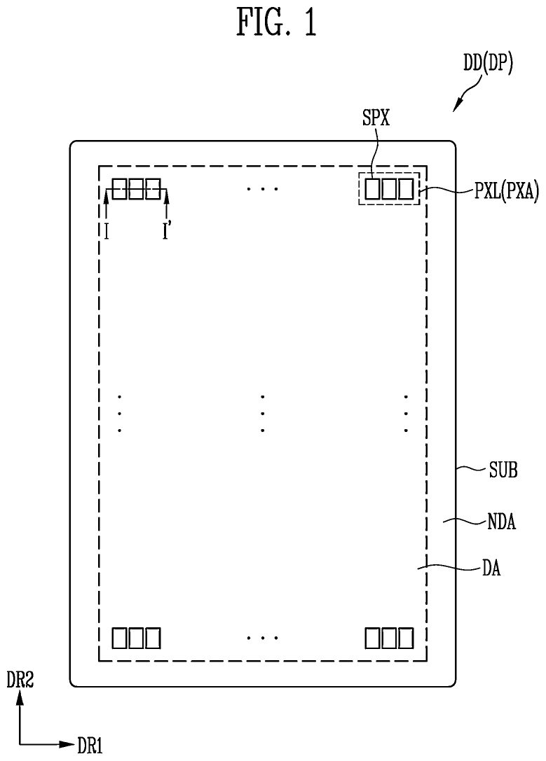

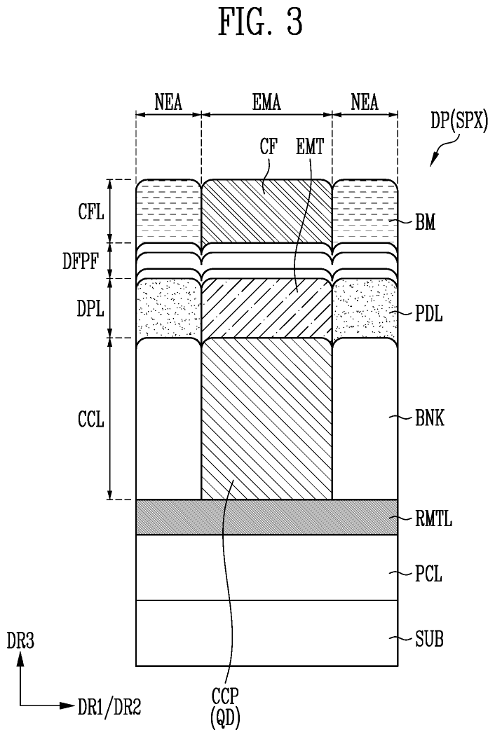

FIG. 1 is a plan view schematically illustrating a display device in accordance with embodiments of the disclosure. In FIG. 3, a display device DD, e.g., a display panel DP provided in the display device DD is schematically illustrated based on a display area DA.

Referring to FIG. 1, the display panel DP (or the display device DD) may display images. A self-luminescent display panel, such as an Organic Light Emitting Display panel (OLED panel) using an organic light emitting diode as a light emitting element, an inorganic light emitting display panel using an inorganic light emitting diode as a light emitting element, or a Quantum Dot Organic Light Emitting Display panel (QD OLED panel) using a quantum dot and an organic light emitting diode, may be used as the display panel DP.

The display panel DP (or the display device DD) may be provided in various shapes. In an embodiment, the display panel DP may be provided in a rectangular plate shape having two pairs of sides parallel to each other, but the disclosure is not limited thereto. In case that the display panel DP is provided in the rectangular plate shape, a pair of sides among the two pairs of sides may be provided longer than another pair of sides.

At least a portion of the display panel DP may have flexibility, and be folded at the portion having the flexibility. However, the disclosure is not limited thereto.

The display panel DP may include a substrate SUB and a pixel PXL provided on the substrate SUB.

The substrate SUB may include a transparent insulating material to enable light to be transmitted therethrough, but the disclosure is not limited thereto. The substrate SUB may be a rigid substrate or a flexible substrate.

The rigid substrate may be, for example, one of a glass substrate, a quartz substrate, a glass ceramic substrate, and a crystalline glass substrate.

The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the disclosure is not limited thereto.

An area of the substrate SUB may be provided as the display area DA such that the pixel PXL is disposed in the display area DA, and another area on the substrate SUB may be provided as a non-display area NDA. For example, the substrate SUB may include the display area DA including a pixel area PXA in which each pixel PXL is disposed and the non-display area NDA disposed at the periphery of the display area DA (or adjacent to the display area DA). A line unit connected to each pixel PXL and a driving unit which is connected to the line unit and drives the pixel PXL may be disposed in the non-display area NDA.

The pixel PXL may display full colors. The pixel PXL may include a sub-pixel SPX. Each sub-pixel SPX may include a light emitting element emitting light and a pixel circuit for driving the light emitting element. The pixel circuit may include at least one transistor electrically connected to the light emitting element. Each sub-pixel SPX may emit light of one color among red, green, and blue, but the disclosure is not limited thereto. The sub-pixel SPX may emit light of one color among cyan, magenta, yellow, and white.

The sub-pixel SPX (or the pixel PXL) may be provided in plurality and arranged in a matrix form along pixel rows extending in a first direction DR1 and pixel columns extending in a second direction DR2 intersecting the first direction DR1. The arrangement of the sub-pixels SPX is not particularly limited, and the sub-pixels SPX may be arranged in various forms. In some embodiments, in case that the sub-pixel SPX is provided in plurality, the sub-pixels SPX may have different areas (or sizes) in a plan view. For example, in the case of sub-pixels SPX having different colors of lights emitted therefrom, the sub-pixels SPX may have different areas (sizes) or different shapes for each color in a plan view.

The driving unit may provide a signal and a voltage to each sub-pixel SPX (or each pixel PXL) through the line unit, thereby controlling driving of the sub-pixel SPX.

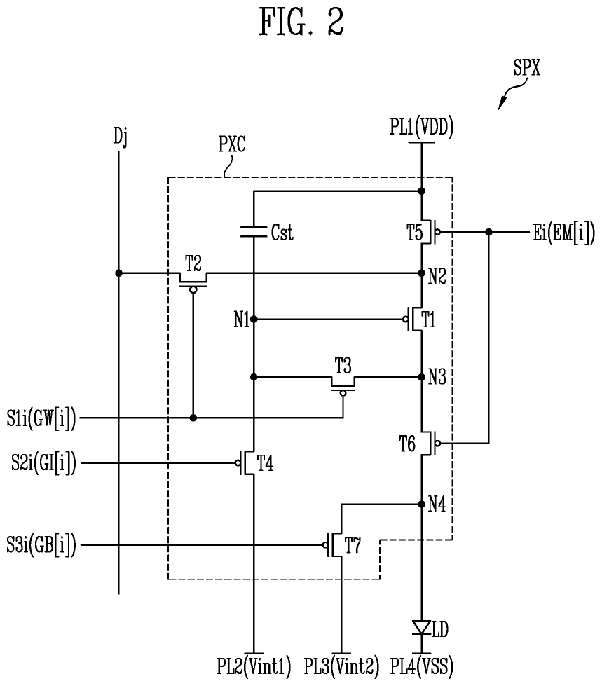

FIG. 2 is a schematic diagram of an equivalent circuit of the sub-pixel included in the display device shown in FIG. 1 in accordance with an embodiment of the disclosure. For convenience of description, a sub-pixel SPX which is located on an ith horizontal line (or ith pixel row) and is connected to a jth data line Dj is illustrated in FIG. 2.

Referring to FIG. 2, the sub-pixel SPX may include a pixel circuit PXC and a light emitting element LD. The pixel circuit PXC may include transistors T1 to T7 and a storage capacitor Cst.

A first electrode (or pixel electrode) of the light emitting element LD may be connected to a fourth node N4, and a second electrode (or common electrode) of the light emitting element LD may be connected to a fourth power line PL4. The light emitting element LD may generate light with a luminance corresponding to an amount of current (or driving current) supplied from a first transistor T1. In an embodiment, the light emitting element LD may be an organic light emitting diode including an organic light emitting layer. However, the disclosure is not limited thereto. In some embodiments, the light emitting element LD may be an inorganic light emitting diode formed of an inorganic material or a light emitting diode configured with a combination of an inorganic material or an organic material.

The first transistor T1 (or driving transistor) may be electrically connected between a first power line PL1 and the first electrode of the light emitting element LD. The first transistor T1 may include a gate electrode electrically connected to a first node N1. The first transistor T1 may control an amount of current (or driving current) flowing from the first power line PL1 to the fourth power line PL4 via the light emitting element LD, based on a voltage of the first node N1. A first power voltage VDD may be provided to the first power line PL1, and a second power voltage VSS may be provided to the fourth power line PL4. The first power voltage VDD may be higher than the second power voltage VSS.

A second transistor T2 may be electrically connected between the jth data line Dj and a second node N2. A gate electrode of the second transistor T2 may be connected to a 1ith scan line S1i (or first scan line). The second transistor T2 may be turned on in case that a first scan signal GW[i] (e.g., a first scan signal having a low level) is supplied to the 1ith scan line S1i, to electrically connect the jth data line Dj and the second node N2 to each other. In case that each of the first transistor T1 and a third transistor T3 is in a turn-on state, the second transistor T2 may transfer a data signal of the jth data line Dj to a first node N1 in response to the first scan signal GW[i].

The third transistor T3 may be electrically connected between the first node N1 and a third node N3. A gate electrode of the third transistor T3 may be electrically connected to the 1ith scan line S1i. The third transistor T3 may be turned on in case that the first scan signal GW[i] is supplied to the 1ith scan line S1i. In case that the third transistor T3 is turned on, the first transistor T1 may have a diode-connected form.

A fourth transistor T4 may be electrically connected between the first node N1 and a second power line PL2. A gate electrode of the fourth transistor T4 may be electrically connected to a 2ith scan line S2i (or second scan line). A first initialization power voltage Vint1 may be provided to the second power line PL2. The fourth transistor T4 may be turned on by a second scan signal GI[i] supplied to the 2ith scan line S2i. In case that the fourth transistor T4 is turned on, the first initialization power voltage Vint1 may be supplied to the first node N1 (i.e., the gate electrode of the first transistor T1).

A fifth transistor T5 may be electrically connected between the first power line PL1 and the second node N2. A gate electrode of the fifth transistor T5 may be electrically connected to an ith emission control line Ei (or emission control line). A sixth transistor T6 may be electrically connected between the third node N3 and the light emitting element LD (or the fourth node N4). A gate electrode of the sixth transistor T6 may be electrically connected to the ith emission control line Ei. The fifth transistor T5 and the sixth transistor T6 may be turned off in case that an emission control signal EM[i] (e.g., the emission control signal EM[i] having a high level) is supplied to the ith emission control line Ei, and be turned on in other cases.

A seventh transistor T7 may be electrically connected between the first electrode of the light emitting element LD (i.e., the fourth node N4) and a third power line PL3. A gate electrode of the seventh transistor T7 may be electrically connected to a 3ith scan line S3i. A second initialization power voltage Vint2 may be provided to the third power line PL3. In some embodiments, the second initialization power voltage Vint2 and the first initialization power voltage Vint1 may be the same or different from each other. The seventh transistor T7 may be turned on by a third scan signal GB[i] supplied to the 3ith scan line S3i, to supply the second initialization power voltage Vint2 to the first electrode of the light emitting element LD.

The storage capacitor Cst may be connected or formed between the first power line PL1 and the first node N1.

However, the pixel circuit PXC shown in FIG. 2 is an embodiment of the disclosure, and is not limited thereto. The pixel circuit PXC may be variously changed within a range in which the amount of current flowing through the light emitting element LD can be controlled in response to the jth data line Dj.

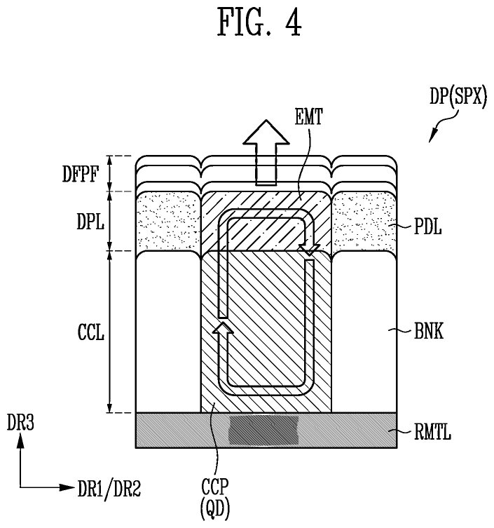

FIG. 3 is a schematic cross-sectional view of the display device shown in FIG. 1 in accordance with an embodiment of the disclosure. In FIG. 3, a structure of a display panel DP is schematically illustrated based on one sub-pixel SPX. FIG. 4 is a schematic cross-sectional view illustrating confinement of light in the display panel shown in FIG. 3.

Referring to FIGS. 1, 3, and 4, the display panel DP (or the sub-pixel SPX) may include a reflective layer RMTL (or reflective electrode), a color conversion layer CCL, a light emitting element layer DPL, and a resonant filter DFPF, which are sequentially disposed on a substrate SUB. In some embodiments, the display panel DP may further include a pixel circuit layer PCL and a color filter layer CFL.

The pixel circuit layer PCL may be provided on the substrate SUB, and include a transistor and signal lines connected to the transistor. For example, the pixel circuit layer PCL may include the transistor included in the pixel circuit PXC shown in FIG. 2. The transistor may have a form in which a source electrode, an active pattern (or semiconductor pattern), and a drain electrode are sequentially stacked with an insulating layer interposed between the active pattern and a gate electrode. The semiconductor pattern may include amorphous silicon, poly-silicon, low temperature poly-silicon, an organic semiconductor, and/or an oxide semiconductor. The gate electrode, a source electrode, and a drain electrode may include at least one of aluminum (Al), copper (Cu), titanium (Ti), and molybdenum (Mo), but the disclosure is not limited thereto. The pixel circuit layer PCL may include at least one insulating layer.

The reflective layer RMTL (or reflective electrode) may be disposed on the pixel circuit layer PCL (or the substrate SUB). The reflective layer RMTL may reflect light (e.g., visible light) incident from the light emitting element layer DPL in a third direction DR3 (i.e., a direction intersecting the first direction DR1 and the second direction DR2 or an image display direction). For example, the reflective layer RMTL may reflect 90% or more of the visible light. The reflective layer RMTL may include an opaque metal. For example, the reflective layer RMTL may include a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof.

The color conversion layer CCL may be disposed on the reflective layer RMTL. The color conversion layer CCL may absorb light in a first wavelength band (e.g., blue light) and emit light in a second wavelength band (e.g., red light or green light).

The color conversion layer CCL may include a bank BNK and a color conversion pattern CCP (or a color conversion particle QD). The bank BNK may be provided in a non-emission area NEA, and the color conversion pattern CCP may be provided in an emission area EMA. The non-emission area NEA and the emission area EMA may be included in the display area DA (or the pixel area PXA) shown in FIG. 1.

The bank BNK may include at least one light blocking material and/or at least one reflective material. The bank BNK may allow light emitted from the color conversion pattern CCP to further advance in the third direction DR3, thereby improving the light emission efficiency of the sub-pixel SPX.

The color conversion pattern CCP may include multiple color conversion particles QD dispersed in a matrix material such as a base resin. For example, the color conversion particles QD may be quantum dots which absorb light in the first wavelength band (e.g., blue light) and emit light in the second wavelength band (e.g., red light or green light) by shifting a wavelength of the light in the first wavelength band according to energy transition.

In some embodiments, a capping layer may be disposed on the color conversion layer CCL, to protect the color conversion layer CCL. The capping layer may be, for example, an inorganic insulating layer including an inorganic material. For example, the capping layer may include silicon nitride (SiNₓ), silicon oxide (SiOₓ), silicon oxynitride (SiOₓN_{y}), aluminum oxide (AlOₓ), or the like.

The light emitting element layer DPL (or display element layer) may be disposed on the color conversion layer CCL. The light emitting element layer DPL may include a pixel defining layer PDL and a light emitting structure EMT (or light emitting layer).

The pixel defining layer PDL may be disposed in the non-emission area NEA, and define or partition the emission area EMA. The pixel defining layer PDL may include an organic insulating layer made of an organic material. For example, the pixel defining layer may include an acrylic resin, an epoxy resin, a phenolic resin, a polyamide resin, a polyimide resin, or the like. In some embodiments, the pixel defining layer PDL may include a light absorption material, or have a light absorber applied thereon, to absorb light introduced from the outside. For example, the pixel defining layer PDL may include a carbon-based black pigment, but the disclosure is not limited thereto.

The pixel defining layer PDL may include an opening exposing a lower component, and the light emitting structure EMT may be disposed in the opening. The light emitting structure EMT may emit light in the first wavelength band (e.g., blue light). For example, the light emitting structure EMT may have a multi-layer thin film structure including a light generation layer (or light emitting layer) for generating light. In an embodiment, the light emitting structure EMT may further include a hole transport material, a hole injection material, an electron transport material, and/or an electron injection material.

The resonant filter DFPF (or resonant filter layer or intermediate layer) may be disposed on the light emitting element layer DPL. The resonant filter DFPF may reflect light in the first wavelength band (e.g., blue light), and transmit light in the second wavelength band (e.g., red light or green light). For example, the resonant filter DFPF may reflect light in the first wavelength band (e.g., blue light) by in a range of about 70% to about 90%, and transmit light in the second wavelength band (e.g., red light or green light) by in a range of about 40% to about 90%.

As shown in FIG. 4, the light emitting structure EMT may emit light in the first wavelength band (e.g., blue light), and the color conversion layer CCL (or the color conversion pattern CCP) may convert light in the first wavelength band into light in the second wavelength band (e.g., red light or green light). According to external quantum efficiency of the color conversion layer CCL (or the color conversion particle QD), partial light of light in the first wavelength band (i.e., light emitted from the light emitting structure EMT) may not be absorbed in the color conversion layer CCL (or the color conversion particle QD) or may not be converted by the color conversion layer CCL (or the color conversion particle QD). The resonant filter DFPF may transmit light in the second wavelength band, and may reflect the partial light in the first wavelength band (i.e., light which is not absorbed or converted). The color conversion layer CCL may re-convert the partial light in the first wavelength band into light in the second wavelength band, and the reflective layer RMTL may reflect both the converted light and the unconverted light in the third direction DR3. As such a process is repeated, light in the first wavelength band may be trapped between the resonant filter DFPF and the reflective layer RMTL. For example, as light in the first wavelength band is recycled, the amount of light in the second wavelength band, which is emitted from the sub-pixel SPX, may increase, and accordingly, the light emission efficiency of the sub-pixel SPX may be improved.

Since the color conversion layer CCL is disposed/formed before the light emitting element layer DPL is formed, a high temperature process of 100 degrees or higher may be applied when the color conversion layer CCL is formed (e.g., an organic material, a gas or the like may be evaporated when the color conversion layer CCL is formed), and the reliability of the display device may be improved.

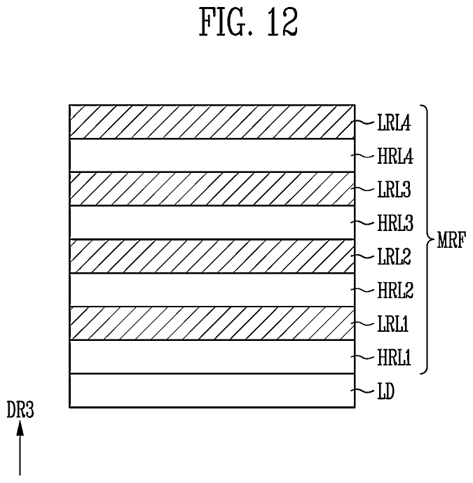

Further, as described below with reference to FIG. 12, the color conversion layer CCL and the light emitting element layer DPL may be sequentially formed between the reflective layer RMTL and the resonant filter DFPF, so that the path of recycled light (i.e., light in the first wavelength band) may be shortened, and the recycled light may be prevented from being absorbed or guided in another layer on the light path. For example, the recycling rate of light in the first wavelength band may be increased, and introduction of the recycled light to another sub-pixel SPX may be prevented or minimized.

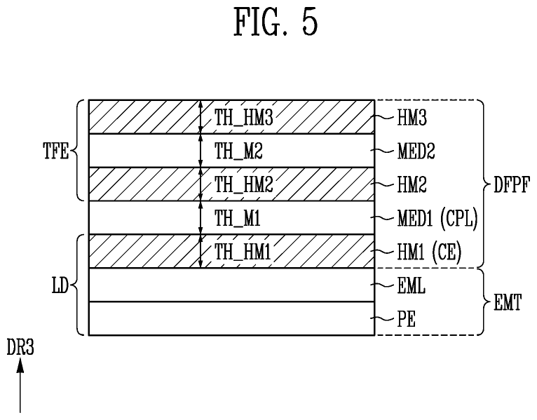

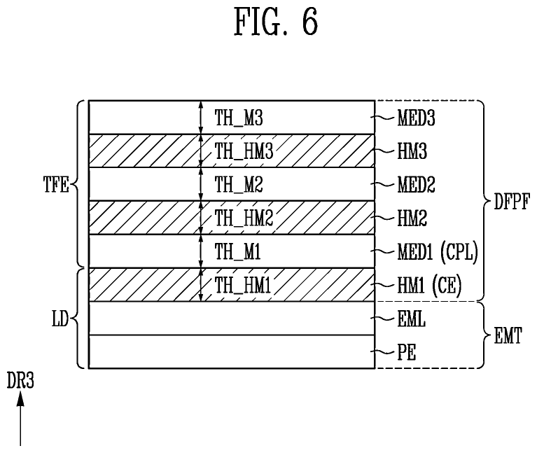

In embodiments, the resonant filter DFPF may include multiple semi-transmission layers and at least one medium layer disposed between semi-transmission layers. The resonant filter DFPF may be a filter having a double Fabry-Perot cavity optical structure. Light may be reflected from semi-transmission layers having a Fabry-Perot cavity structure, reflected lights may interfere with each other or be cancelled, and only light in a specific wavelength band may be transmitted through the filter. Due to the double Fabry-Perot cavity structure, light in the first wavelength band may be reflected, and light in the second wavelength band may be transmitted. The resonant filter DFPF will be described below with reference to FIGS. 5 and 6.

The color filter layer CFL may be disposed on the resonant filter DFPF. The color filter layer CFL may include a color filter CF and a light blocking pattern BM. The color filter CF may be disposed corresponding to the light emitting structure EMT. The light blocking pattern BM may be disposed in the non-emission area NEA. The light blocking pattern BM may include a light blocking material. In an embodiment, the light blocking pattern BM may be a black matrix, but the disclosure is not limited thereto. In some embodiments, the light blocking pattern BM may include at least one light blocking material and/or at least one reflective material, to allow light emitted from the color conversion layer CCL to further advance in the image display direction of the display device DD, thereby improving light emission efficiency.

As described above, the color conversion layer CCL, the light emitting element layer DPL (or the light emitting structure EMT), and the resonant filter DFPF may be sequentially disposed on the reflective layer RMTL, and the resonant filter DFPF may reflect light in the first wavelength band (e.g., blue light), which is emitted from the light emitting element layer DPL, and transmit light in the second wavelength band (i.e., light converted in the color conversion layer CCL, e.g., red light or green light), which is emitted from the color conversion layer CCL. Thus, the recycling rate of light in the first wavelength band may be increased, and the amount of light in the second wavelength band may be increased. For example, the light emission efficiency may be improved.

FIGS. 5 and 6 are schematic cross-sectional views of the resonant filter included in the display device shown in FIG. 3 in accordance with an embodiment of the disclosure. For convenience of description, a light emitting structure EMT is schematically illustrated in FIGS. 5 and 6.

Referring to FIGS. 5 and 6, the light emitting structure EMT may include a pixel electrode PE (or first electrode) and a light emitting layer EML. The pixel electrode PE may be an anode electrode of a light emitting element LD. The pixel electrode PE may include a transparent conductive material. For example, the pixel electrode PE may include a conductive oxide such as indium tin oxide (ITO), indium zinc oxide (IZO), zinc oxide (ZnO), indium gallium zinc oxide (IGZO), or indium tin zinc oxide (ITZO), a conductive polymer such as poly(3,4-ethylenedioxythiophene (PEDOT), and the like. Holes and electrons may be combined in the light emitting layer EML, thereby generating light.

The resonant filter DFPF may include a first semi-transmission layer HM1, a first medium layer MED1, a second semi-transmission layer HM2, a second medium layer MED2, and a third semi-transmission layer HM3, which are sequentially stacked in the third direction DR3 on the light emitting structure EMT.

The first semi-transmission layer HM1, the second semi-transmission layer HM2, and the third semi-transmission layer HM3 may include a same material. In an embodiment, the first semi-transmission layer HM1, the second semi-transmission layer HM2, and the third semi-transmission layer HM3 may include a conductive material. In an embodiment, the first semi-transmission layer HM1, the second semi-transmission layer HM2, and the third semi-transmission layer HM3 may be configured with a metal thin film. In an embodiment, each of the first semi-transmission layer HM1, the second semi-transmission layer HM2, and the third semi-transmission layer HM3 may be formed as a single layer including silver (Ag), magnesium (Mg), aluminum (Al), or an alloy thereof. In some embodiments, each of the first semi-transmission layer HM1, the second semi-transmission layer HM2, and the third semi-transmission layer HM3 may be formed as a multi-layer. In order to allow light to be semi-transmitted, each of a thickness TH_HM1 of the first semi-transmission layer HM1, a thickness TH_HM2 of the second semi-transmission layer HM2, and a thickness TH_HM3 of the third semi-transmission layer HM3 in the third direction DR3 may be less than or equal to about 30 nm.

The first semi-transmission layer HM1, the second semi-transmission layer HM2, and the third semi-transmission layer HM3 may include a same conductive material, but the disclosure is not limited thereto. In some embodiments, at least some of the first semi-transmission layer HM1, the second semi-transmission layer HM2, and the third semi-transmission layer HM3 may include different conductive materials.

Each of the first medium layer MED1 and the second medium layer MED2 may be an organic layer including an organic material or an inorganic layer including an inorganic material. For example, each of the first medium layer MED1 and the second medium layer MED2 may include at least one of a transparent organic layer, titanium oxide, silicon oxide, silicon nitride, and silicon oxynitride. In some embodiments, the first medium layer MED1 and the second medium layer MED2 may include a transparent conductive oxide such as indium tin oxide or indium zinc oxide. The first medium layer MED1 and the second medium layer MED2 may include a same material, but the disclosure is not limited thereto. In some embodiments, the first medium layer MED1 and the second medium layer MED2 may include different materials.

In an embodiment, the thickness TH_HM1 of the first semi-transmission layer HM1, the thickness TH_HM2 of the second semi-transmission layer HM2, and the thickness TH_HM3 of the third semi-transmission layer HM3 in the third direction DR3 may be the same. However, the disclosure is not limited thereto. In some embodiments, the thickness TH_HM1 of the first semi-transmission layer HM1, the thickness TH_HM2 of the second semi-transmission layer HM2, and the thickness TH_HM3 of the third semi-transmission layer HM3 in the third direction DR3 may be different from one another. In other embodiments, at least two layers among the first semi-transmission layer HM1, the second semi-transmission layer HM2, and the third semi-transmission layer HM3 may have a same thickness, and another layer may have a thickness different from the thicknesses of the two layers.

In an embodiment, a refractive index of each of the first medium layer MED1 and the second medium layer MED2 may be in a range of about 1.3 to about 2.5. Each of the first medium layer MED1 and the second medium layer MED2 may have a thickness less than or equal to about 1 μm. A thickness TH_M1 of the first medium layer MED1 and a thickness TH_M2 of the second medium layer MED2 in the third direction DR3 may be the same. However, the disclosure is not limited thereto. In some embodiments, the thickness TH_M1 of the first medium layer MED1 and the thickness TH_M2 of the second medium layer MED2 in the third direction DR3 may be different from each other. In case that the thickness TH_M1 of the first medium layer MED1 and the thickness TH_M2 of the second medium layer MED2 are different from each other, one of the first medium layer MED1 and the second medium layer MED2 may be designed not to have a thickness which is two times or more of a thickness of another one of the first medium layer MED1 and the second medium layer MED2.

The first medium layer MED1 as a dielectric layer may be disposed between the first semi-transmission layer HM1 and the second semi-transmission layer HM2, which are configured with a metal thin film. The second medium layer MED2 as a dielectric layer may be disposed between the second semi-transmission layer HM2 and the third semi-transmission layer HM3, which are configured with a metal thin film. The resonant filter DFPF including the first semi-transmission layer HM1, the first medium layer MED1, the second semi-transmission layer HM2, the second medium layer MED2, and the third semi-transmission layer HM3, which are sequentially stacked, may be configured with a double Fabry-Perot cavity structure having a metal (semi-transmission layer)-dielectric-metal (semi-transmission layer)-dielectric-metal (semi-transmission layer) structure. Each of the first semi-transmission layer HM1, the second semi-transmission layer HM2 and the third semi-transmission layer HM3, which are configured with a metal thin film, may serve as a half mirror, and each of the first medium layer MED1 and the second medium layer MED2 may serve as a medium for determining a transmittance and a reflectance for each wavelength band, using the refractive index and thickness. In case that the first medium layer MED1 and the second medium layer MED2, each of which serves as the medium, have different thicknesses, the wavelength band in which a resonance effect of the resonant filter DFPF occurs may be extended.

The resonant filter DFPF including the first semi-transmission layer HM1, the first medium layer MED1, the second semi-transmission layer HM2, the second medium layer MED2, and the third semi-transmission layer HM3, which are sequentially stacked, may be configured to reflect light in a specific wavelength band. In an embodiment, the resonant filter DFPF may reflect more than or equal to about 60% of light in a wavelength band in a range of about 420 nm to about 480 nm (e.g., light in a first wavelength band) and guide the reflected light to the light emitting structure EMT. For example, the resonant filter DFPF may reflect in a range of about 70% to about 90% of light in a wavelength band in a range of about 420 nm to about 480 nm (e.g., light in a first wavelength band).

In an embodiment, the resonant filter DFPF may transmit light in a second wavelength band different from light in the first wavelength band. The light in the second wavelength band may include light in a wavelength band in a range of about 520 nm to about 580 nm (e.g., green light) and light in a wavelength band in a range of about 620 nm to about 680 nm (e.g., red light). In an embodiment, the resonant filter DFPF may transmit more than or equal to about 40% of light in a wavelength band in a range of about 520 nm to about 680 nm (e.g., green light and red light). For example, the resonant filter DFPF may transmit in a range of about 40% to about 90% of light in a wavelength band in a range of about 520 nm to about 680 nm (e.g., green light and red light).

In an embodiment, the first semi-transmission layer HM1 may serve as a common electrode CE (or cathode electrode) of the light emitting element LD, and the first medium layer MED1 may serve as a capping layer CPL for protecting the common electrode CE. For example, the capping layer CPL may include an inorganic material.

In an embodiment, as shown in FIG. 5, the second semi-transmission layer HM2, the second medium layer MED2, and the third semi-transmission layer HM3 may serve as an encapsulation layer TFE (or thin film encapsulation). For example, a portion of the resonant filter DFPF may serve as the encapsulation layer TFE. For example, the second medium layer MED2 may include an organic material. The second semi-transmission layer HM2 and the third semi-transmission layer HM3 may prevent introduction of moisture, and the second medium layer MED2 may prevent introduction of dust.

In an embodiment, as shown in FIG. 6, the resonant filter DFPF may further include a third medium layer MED3 (or capping layer) disposed on the third semi-transmission layer HM3. For example, the third medium layer MED3 may be an inorganic insulating layer including an inorganic material. The third medium layer MED3 may protect the third semi-transmission layer HM3 as a metal thin film. A thickness TH_M3 of the third medium layer MED3 and each of the thicknesses TH_M1 and TH_M2 of the first and second medium layers MED1 and MED2 may be equal or different from each other.

In an embodiment, the resonant filter DFPF may be served as a encapsulation layer TFE. For example, each of the first medium layer MED1 and the third medium layer MED3 may be an inorganic layer, and the second medium layer MED2 may be an organic layer. The first medium layer MED1, the second medium layer MED2, and the third medium layer MED3, which are sequentially stacked, may serve as an encapsulation layer or constitute an encapsulation layer.

In case that at least a portion of the resonant filter DFPF serves as the encapsulation layer TFE, the resonant filter DFPE may be disposed on (e.g., directly disposed on) the light emitting structure EMT. Thus, the distance between the reflective layer RMTL described with reference to FIG. 4 and the resonant filter DFPF (i.e., the path of recycled light) may be shortened, and light emission efficiency may be improved.

As described above, the resonant filter DFPF may reflect 60% or more of blue light, so that the recycling rate of the blue light may be increased. Also, the resonant filter DFPF may transmit 40% or more of incident red light and transmit 40% or more of incident green light, so that loss of the red light and the green light may be reduced. The characteristic control of the resonant filter DFPF which reflects 60% or more of blue light and transmits 40% or more of each of red light and green light may be controlled according to the thickness, material, and the like of each of the first semi-transmission layer HM1, the first medium layer MED1, the second semi-transmission layer HM2, the second medium layer MED2, and the third semi-transmission layer HM3.

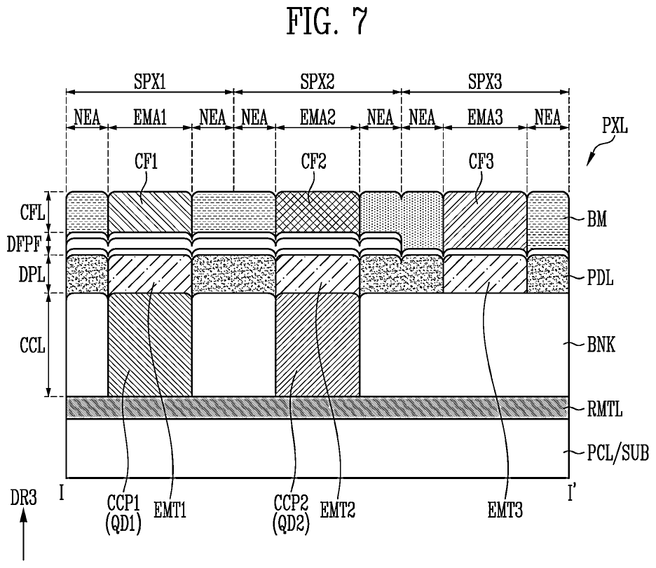

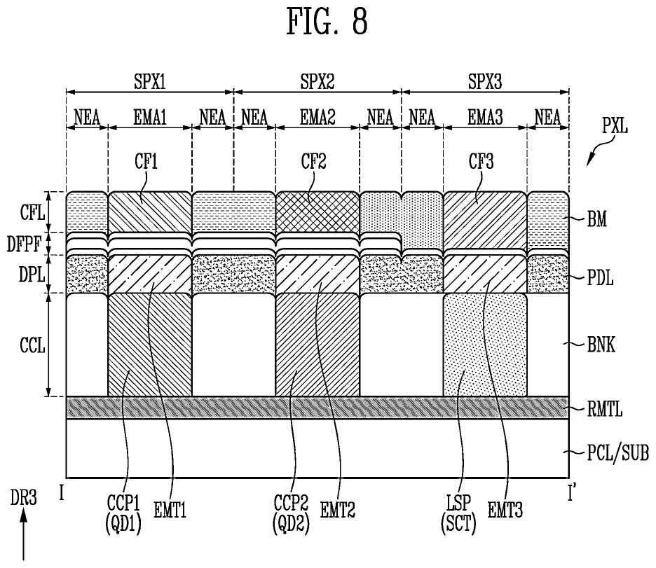

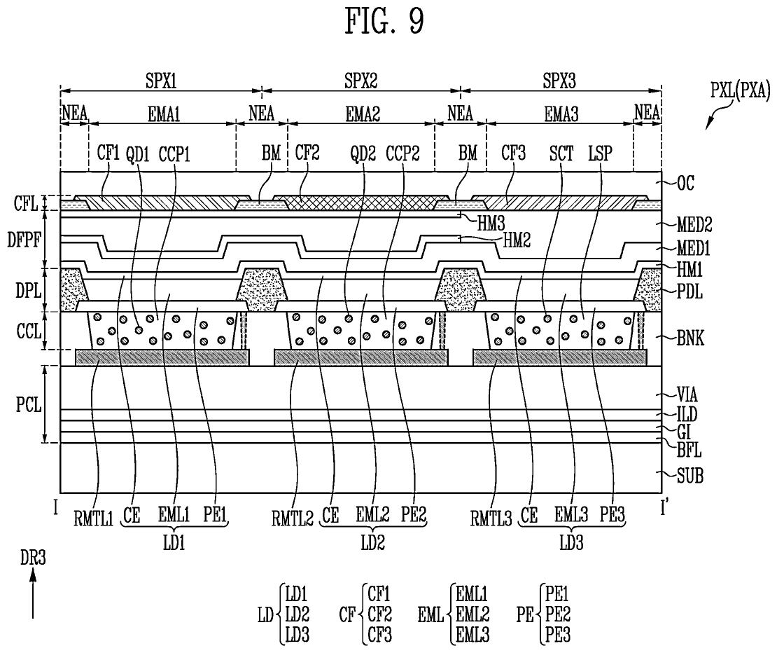

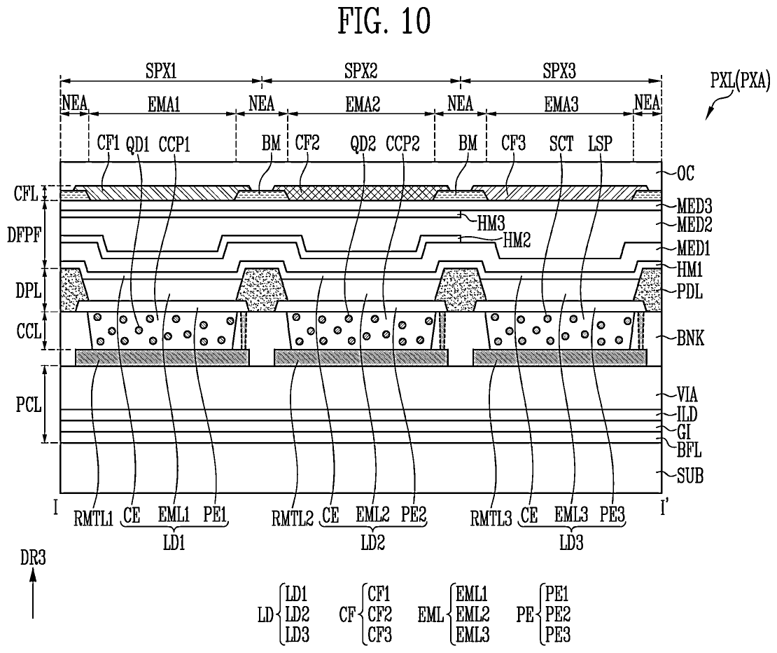

FIGS. 7 and 8 are schematic cross-sectional views of the pixel taken along line I-I′ shown in FIG. 1 in accordance with an embodiment of the disclosure. FIGS. 9 and 10 are schematic cross-sectional views of the pixel taken along the line I-I′ shown in FIG. 1 in accordance with an embodiment of the disclosure.

In relation to the embodiments shown in FIGS. 7 to 10, portions different from those of the above-described embodiments (e.g., the embodiment shown in FIGS. 3 to 6) will be described to avoid redundancy.

Referring to FIGS. 1 to 10, the pixel PXL may be disposed in a pixel area PXA of the display area DA. The pixel area PXA may include emission areas EMA1 to EMA3 and a non-emission area NEA.

The pixel PXL may include a first sub-pixel SPX1, a second sub-pixel SPX2, and a third sub-pixel SPX3. The first sub-pixel SPX1 may emit red light (or light of a first color), the second sub-pixel SPX2 may emit green light (or light of a second color), and the third sub-pixel SPX3 may emit blue light (or light of a third color). However, the disclosure is not limited to the above-described example.

The first sub-pixel SPX1 may include a first emission area EMA1 and the non-emission area NEA adjacent to the first emission area EMA1 (or surrounding at least one side of the first emission area EMA1). The second sub-pixel SPX2 may include a second emission area EMA2 and the non-emission area NEA adjacent to the second emission area EMA2 (or surrounding at least one side of the second emission area EMA2). The third sub-pixel SPX3 may include a third emission area EMA3 and the non-emission area NEA adjacent to the third emission area EMA3 (or surrounding at least one side of the third emission area EMA3).

Each of the first, second, and third sub-pixels SPX1, SPX2, and SPX3 may include a substrate SUB, a pixel circuit layer PCL, a reflective layer RMTL, a color conversion layer CCL, a light emitting element layer DPL, and a color filter layer CFL. A resonant filter DFPF may be disposed in the first and second sub-pixels SPX1 and SPX2, and only some layers of the resonant filter DFPF may be disposed in the third sub-pixel SPX3. The resonant filter DFPF does not function with only some layers of the resonant filter DFPF. Therefore, the resonant filter DFPF may be not actually disposed in the third sub-pixel SPX3.

The substrate SUB may include a transparent insulating material that transmits light. The substrate SUB may be a rigid substrate or a flexible substrate.

Circuit elements constituting a pixel circuit PXC (see FIG. 3) of each of the first to third sub-pixels SPX1, SPX2, and SPX3 and signal lines electrically connected to the circuit elements may be disposed in the pixel circuit layer PCL. At least one insulating layer may be disposed in the pixel circuit layer PCL. In an embodiment, as shown in FIG. 9, a buffer layer BFL, a gate insulating layer GI, an interlayer insulating layer ILD, and a via layer VIA may be disposed in the pixel circuit layer PCL.

The buffer layer BFL may be entirely disposed on the substrate SUB. The buffer layer BFL may prevent an impurity from being diffused into transistors, e.g., the transistors T1 to T7 (see FIG. 3) included in the pixel circuit PXC. The buffer layer BFL may be an inorganic insulating layer including an inorganic material (or substance). The buffer layer BFL may be provided as a single layer or a multi-layer. In an embodiment, the buffer layer BFL may be omitted according to a material of the substrate SUB, a process condition, and the like.

The gate insulating layer GI may be entirely disposed on the buffer layer BFL. The gate insulating layer GI and the buffer layer BFL may include a same material, or the gate insulating layer GI may include a material that can be used for the material constituting the buffer layer BFL. In an embodiment, the gate insulating layer GI may include an inorganic insulting layer including an inorganic material. In some embodiments, the gate insulating layer GI may be partially disposed on the buffer layer BFL.

The interlayer insulating layer ILD may be entirely provided and/or formed on the gate insulating layer GI. The interlayer insulating layer ILD and the buffer layer BFL may include a same material, or the interlayer insulating layer ILD may include a material that can be used for the buffer layer BFL.

The via layer VIA may be entirely provided and/or formed on the interlayer insulating layer ILD. The via layer VIA may be an insulating layer including an organic material. However, the disclosure is not limited thereto. In an embodiment, the via layer VIA may include an inorganic material.

The reflective layer RMTL may be disposed on the pixel circuit layer PCL (or the via layer VIA).

In an embodiment, as shown in FIG. 9, the reflective layer RMTL may include a first reflective electrode RMTL1 (or first reflective pattern), a second reflective electrode RMTL2 (or second reflective pattern), and a third reflective electrode RMTL3 (or third reflective pattern), which are separated from each other. The first reflective electrode RMTL1 may be provided in the first sub-pixel SPX1, the second reflective electrode RMTL2 may be provided in the second sub-pixel SPX2, and the third reflective electrode RMTL3 may be provided in the third sub-pixel SPX3.

The color conversion layer CCL may be disposed on the reflective layer RMTL. The color conversion layer CCL may include a bank BNK and first and second color conversion patterns CCP1 and CCP2. In some embodiments, the color conversion layer CCL may further include a light scattering pattern LSP.

The bank BNK may define a position of each of the first color conversion pattern CCP1, the second color conversion pattern CCP2, and the light scattering pattern LSP, thereby defining the first emission area EMA1, the second emission area EMA2, and the third emission area EMA3. The bank BNK may surround each of the first color conversion pattern CCP1, the second color conversion pattern CCP2, and the light scattering pattern LSP in a plan view.

The bank BNK may include a least one light blocking material and/or at least one reflective material to allow light emitted from each of the first color conversion pattern CCP1, the second color conversion pattern CCP2, and the light scattering pattern LSP to further advance in the third direction DR3, thereby improving the light emission efficiency of each pixel PXL.

The first color conversion pattern CCP1 may include multiple first color conversion particles QD1 dispersed in a matrix material such as a base resin. For example, the first color conversion particles QD1 may be red quantum dots which absorb incident blue light and emit red light by shifting a wavelength of the blue light according to energy transition. The first sub-pixel SPX1 may be a red pixel. The first color conversion pattern CCP1 may be disposed in at least the first emission area EMA1.

The second color conversion pattern CCP2 may include multiple second color conversion particles QD2 dispersed in a matrix material such as a base resin. For example, the second color conversion particles QD2 may be green quantum dots which absorb incident blue light and emit green light by shifting a wavelength of the blue light according to energy transition. The second sub-pixel SPX2 may be a green pixel. The second color conversion pattern CCP2 may be disposed in at least the second emission area EMA2.

The light scattering pattern LSP may include multiple light scattering particles SCT dispersed in a matrix material such as a base resin. The light scattering pattern LSP may include light scattering particles SCT such as silica, but the material constituting the light scattering particles SCT is not limited thereto. In some embodiments, the light scattering particles SCT may be omitted, and the light scattering pattern LSP configured with a transparent polymer may be provided. The third sub-pixel SPX3 may be a blue pixel. The light scattering pattern LSP may be disposed in at least the third emission area EMA3.

In some embodiments, as shown in FIG. 7, the light scattering pattern LSP may be omitted. The bank BNK may include openings for the first and second color conversion patterns CCP1 and CCP2 in the first and second sub-pixels SPX1 and SPX2, and may not include an opening in the third sub-pixel SPX3.

In an embodiment, a capping layer may be disposed on the color conversion layer CCL between the color conversion layer CCL and the light emitting element layer DPL, to protect the color conversion layer CCL. The capping layer may be, for example, an inorganic insulating layer including an inorganic material.

The light emitting element layer DPL may be disposed on the color conversion layer CCL. Light emitting structures EMT1 to EMT3 (or a light emitting element LD) (see FIG. 9) and a pixel defining layer PDL may be disposed in the light emitting element layer DPL.

A first light emitting structure EMT1 (or a first light emitting element LD1) may be disposed in the light emitting element layer DPL of the first sub-pixel SPX1, a second light emitting structure EMT2 (or a second light emitting element LD2) may be disposed in the light emitting element layer DPL of the second sub-pixel SPX2, and a third light emitting structure EMT3 (or a third light emitting element LD3) may be disposed in the light emitting element layer DPL of the third sub-pixel SPX3.

As described with reference to FIG. 4, the light emitting structures EMT1 to EMT3 and the light emitting element LD may be divided according to whether a common electrode CE is included. Hereinafter, for convenience of description, an embodiment with the light emitting element LD will be described.

As shown in FIG. 9, the first light emitting element LD1 may include a first pixel electrode PE1, a first light emitting layer EML1, and a common electrode CE. The second light emitting element LD2 may include a second pixel electrode PE2, a second light emitting layer EML2, and the common electrode CE. The third light emitting element LD3 may include a third pixel electrode PE3, a third light emitting layer EML3, and a common electrode CE.

The first pixel electrode PE1, the second pixel electrode PE2, and the third pixel electrode PE3 may be disposed on the color conversion layer CCL. The first pixel electrode PE1, the second pixel electrode PE2, and the third pixel electrode PE3 may constitute a pixel electrode PE. Each of the first pixel electrode PE1, the second pixel electrode PE2, and the third pixel electrode PE3 may be configured with a transparent conductive material.

In an embodiment, the first pixel electrode PE1 may be in contact with or connected to the first reflective electrode RMTL1 through a contact hole penetrating the bank BNK in the non-emission area NEA, and be electrically connected to a transistor of the pixel circuit layer PCL through the first reflective electrode RMTL1. Similarly, the second pixel electrode PE2 may be connected to the second reflective electrode RMTL2 through a contact hole, and the third pixel electrode PE3 may be connected to the third reflective electrode RMTL3 through a contact hole. However, the disclosure is not limited thereto. For example, the first pixel electrode PE1 may be not in contact with the first reflective electrode RMTL1, and may be connected directly to the transistor of the pixel circuit layer PCL or be electrically connected to the transistor through a bridge pattern different from the first reflective electrode RMTL1.

The pixel defining layer PDL may be provided on the color conversion layer CCL in the non-emission area NEA, and define (or partition) the first emission area EMA1, the second emission area EMA2, and the third emission area EMA3. The pixel defining layer PDL may be an organic insulating layer.

The pixel defining layer PDL may include an opening exposing an area of each of the first pixel electrode PE1, the second pixel electrode PE2, and the third pixel electrode PE3, and protrude in the third direction DR3 from the color conversion layer CCL along the circumference of each of the first to third emission areas EMA1, EMA2, and EMA3.

A light emitting layer EML may be disposed on each of the first, second, and third pixel electrodes PE1, PE2, and PE3, which is exposed by the opening of the pixel defining layer PDL. In an embodiment, the first light emitting layer EML1 may be disposed on the first pixel electrode PE1 exposed by an opening of the pixel defining layer PDL, the second light emitting layer EML2 may be disposed on the second pixel electrode PE2 exposed by another opening of the pixel defining layer PDL, and the third light emitting layer EML3 may be disposed on the third pixel electrode PE3 exposed by another opening of the pixel defining layer PDL.

Each of the first light emitting layer EML1, the second light emitting layer EML2, and the third light emitting layer EML3 may be supplied to a desired area of a corresponding sub-pixel SPX (e.g., a pixel electrode exposed by an opening of the pixel defining layer PDL), using a deposition method, an inkjet printing method, or the like, but the disclosure is not limited thereto.

Each of the first light emitting layer EML1, the second light emitting layer EML2, and the third light emitting layer EML3 may have a multi-layer thin film structure including a light generation layer for generating light, and layers of the multi-layer thin film structure may be formed as one layer in which the layers are connected to each other without being independently divided by a fine metal mask or the like.

The common electrode CE may be disposed on the first, second, and third light emitting layers EML1, EML2, and EML3. The common electrode CE may be commonly provided in the first to third sub-pixels SPX1, SPX2, and SPX3. The common electrode CE may be provided in a plate shape throughout the entire area of the display area DA (see FIG. 1), but the disclosure is not limited thereto. The common electrode CE may be a thin metal layer having a thickness to a degree to which the common electrode CE can transmit blue light or celadon light obtained by mixing blue and green, which is emitted from each of the first to third light emitting layers EML1, EML2, and EML3.

The resonant filter DFPF may be disposed on the light emitting element layer DPL. The resonant filter DFPF may be formed on the light emitting element layer DPL through a continuous process.

The resonant filter DFPF may be an optical filter layer which reflects (or blocks) light in a specific wavelength band and transmits light in another wavelength band. In an embodiment, the resonant filter DFPF may reflect blue light and transmit red light and/or green light.

As shown in FIG. 9, the resonant filter DFPF may include a first semi-transmission layer HM1, a first medium layer MED1, a second semi-transmission layer HM2, a second medium layer MED2, and a third semi-transmission layer HM3, which are sequentially stacked in the third direction DR3 on the light emitting element layer DPL.

The first semi-transmission layer HM1 may be the common electrode CE.

The first medium layer MED1 may be disposed on the first semi-transmission layer HM1. The first medium layer MED1 may be disposed throughout the entire area of the display area DA (see FIG. 1).

The second semi-transmission layer HM2 may be disposed in the first and second sub-pixels SPX1 and SPX2, and may not be disposed in the third sub-pixel SPX3. Blue light emitted from the third light emitting element LD3 (or the third light emitting structure EMT3) may be not reflected in the opposite direction of the third direction DR3, and may advance toward an upper component (e.g., a third color filter CF3).

The second medium layer MED2 may be disposed on the second semi-transmission layer HM2. The second medium layer MED2 may be disposed throughout the entire area of the display area DA (see FIG. 1).

The third semi-transmission layer HM3 may be disposed in the first and second sub-pixels SPX1 and SPX2, and may not be disposed in the third sub-pixel SPX3.

In the first sub-pixel SPX1, the resonant filter DFPF may not react with the first color conversion pattern CCP1, and may reflect more than or equal to about 60% of light in a first wavelength band to the first color conversion pattern CCP1 to react with the first color conversion pattern CCP1. The light in the first wavelength band, which is reflected to the first color conversion pattern CCP1, may be emitted as red light by reacting with the first color conversion particles QD1. As the recycling rate of the light in the first wavelength band (e.g., blue light) in the first color conversion pattern CCP1 increases, an amount of red light emitted from the first color conversion pattern CCP1 may increase. Accordingly, the light emission efficiency of the first color conversion pattern CCP1 may be improved.

In the second sub-pixel SPX2, the resonant filter DFPF may not react with the second color conversion pattern CCP2, and may reflect more than or equal to about 60% of light in the first wavelength band to the second color conversion pattern CCP2 to react with the second color conversion pattern CCP2. The light in the first wavelength band, which is reflected to the second color conversion pattern CCP2, may be emitted as green light by reacting with the second color conversion particles QD2. As the recycling rate of the light in the first wavelength band (e.g., blue light) in the second color conversion pattern CCP2 increases, an amount of green light emitted from the second color conversion pattern CCP2 may increase. Accordingly, the light emission efficiency of the second color conversion pattern CCP2 may be improved.

In an embodiment, as shown in FIG. 10, the resonant filter DFPF may further include a third medium layer MED3 disposed on the third semi-transmission layer HM3. The third medium layer MED3 may be disposed throughout the entire area of the display area DA (see FIG. 1). The first medium layer MED1, the second medium layer MED2, and the third medium layer MED3, which are sequentially stacked, may serve as the encapsulation layer TFE (see FIG. 6).

The color filter layer CFL may be disposed on the resonant filter DFPF. The color filter layer CFL may include a color filter CF and a light blocking pattern BM. The color filter CF may include a first color filter CF1, a second color filter CF2, and a third color filter CF3.

The first color filter CF1 may be disposed corresponding to the first light emitting layer EML1. The second color filter CF2 may be disposed corresponding to the second light emitting layer EML2. The third color filter CF3 may be disposed corresponding to the third light emitting layer EML3.

The light blocking pattern BM may be located adjacent to the first to third color filters CF1, CF2, and CF. Also, the light blocking pattern BM may be disposed corresponding to the pixel defining layer PDL (or the bank BNK) in the non-emission area NEA. The light blocking pattern BM may prevent color mixture of lights emitted from the first to third color filters CF1, CF2, and CF3.

Each of the first, second, and third color filters CF1, CF2, and CF3 may include a colorant, such as a dye or a pigment, which absorbs wavelengths except a corresponding color wavelength. The first color filter CF1 may be a red color filter, the second color filter CF2 may be a green color filter, and the third color filter CF3 may be a blue color filter. Although an embodiment that adjacent color filters CF are spaced apart from each other with the light blocking pattern BM interposed between adjacent color filters CF is illustrated in the drawing, the adjacent color filters CF may at least partially overlap with each other on the light blocking pattern BM. In some embodiments, the first to third color filters CF1, CF2, and CF3 may be used as light blocking members overlap with each other in the non-emission area NEA to block light interference between adjacent sub-pixels SPX. In an embodiment, the light blocking pattern BM may be omitted.

In an embodiment, as shown in FIG. 9, an overcoat layer OC may be disposed on the color filter layer CFL. The overcoat layer OC may be disposed over the color filter layer CFL and cover a lower member including the color filter layer CFL. The overcoat layer OC may prevent external moisture, external air, or the like from infiltrating into the color filter layer CFL and damaging or contaminating the color filter layer CFL. Also, the overcoat layer OC may prevent a colorant of the color filter layer CFL from being diffused into another component. The overcoat layer OC may include an inorganic insulating layer including an inorganic material, but the disclosure is not limited thereto.

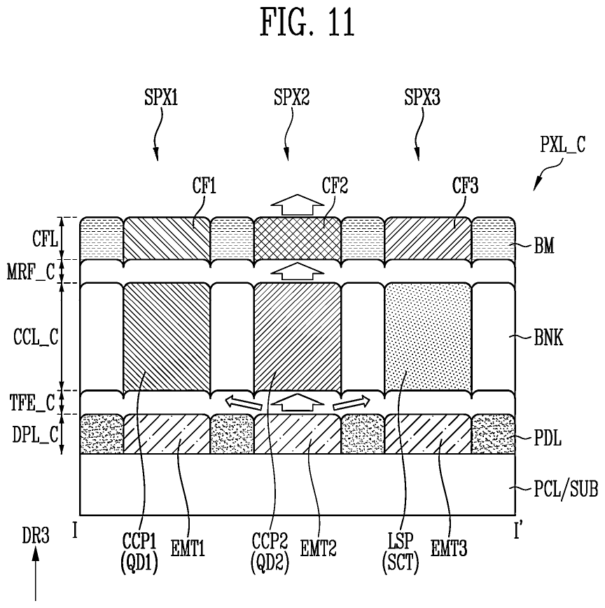

FIG. 11 is a schematic cross-sectional view illustrating a comparative example of the pixel taken along the line I-I′ shown in FIG. 1.

Referring to FIGS. 7 and 11, a pixel PXL_C may include a light emitting element layer DPL_C, an encapsulation layer TFE_C, a color conversion layer CCL_C, a multi-layer semi-transmission filter (MRF_C), and a color filter layer CFL, which are sequentially disposed on a substrate SUB. The light emitting element layer DPL_C, the color conversion layer CCL_C, and the multi-layer semi-transmission filter (MRF_C) may be respectively similar to the light emitting element layer DPL, the color conversion layer CCL, and the resonant filter DFPF, which are shown in FIG. 7, except arrangement positions thereof. Therefore, overlapping descriptions will not be repeated.

The encapsulation layer TFE_C may be disposed on the light emitting element layer DPL_C. The encapsulation layer TFE_C may be an encapsulation substrate or be provided in the form of an encapsulation film formed as a multi-layer. In case that the encapsulation layer TFE_C has the form of the encapsulation film, the encapsulation layer TFE_C may be provided in a form in which an inorganic layer, an organic layer, and an inorganic layer are sequentially stacked. For example, the encapsulation layer TFE_C may have a thickness of about 3 μm. The light emitting element layer DPL_C may have a thickness in a range of about 300 nm to about 700 nm.

The multi-layer semi-transmission filter MRF_C may be a low refractive layer having a refractive index of about 1.24. The multi-layer semi-transmission filter MRF_C may reflect light in a first wavelength band, which is not absorbed/converted in the color conversion layer CCL_C, to the color conversion layer CCL_C.

In order to recycle the light in the first wavelength band, a reflecting plate may be disposed between the color conversion layer CCL_C and the light emitting element layer DPL_C, or an electrode (e.g., an anode electrode) of the light emitting element layer DPL_C (or light emitting structures EMT1 to EMT3) may be used as the reflecting plate.

However, in case that the reflecting plate is disposed between the color conversion layer CCL_C and the light emitting element layer DPL_C, an amount of the light in the first wavelength band, which is emitted from the light emitting structures EMT1 to EMT3 to reach the color conversion layer CCL_C, may be decreased.

In case that the electrode of the light emitting element layer DPL_C (or the light emitting structures EMT1 to EMT3) is used as the reflecting plate, a light path may be lengthened by the encapsulation layer TFE_C, and recycling efficiency may be deteriorated as light is absorbed in or guided to another layer. As the light in the first wavelength band is introduced to an adjacent pixel by the encapsulation layer TFE_C, color mixture may occur.

Thus, as described with reference to FIG. 3, in the display device in accordance with embodiments of the disclosure, the color conversion layer CCL, the light emitting element layer DPL (or the light emitting structure EMT), and the resonant filter DFPF may be sequentially disposed on the reflective layer RMTL. Since the encapsulation layer TFE_C shown in FIG. 11 is excluded, the light path may be shortened, the recycling rate of the light in the first wavelength band may be increased, and recycled light may be prevented from being introduced to another sub-pixel.

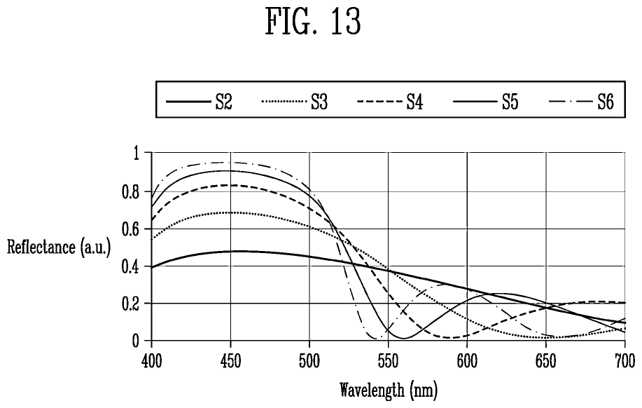

FIG. 12 is a schematic cross-sectional view illustrating an embodiment of a multi-layer semi-transmission filter. FIG. 13 is a graph illustrating a reflectance of the multi-layer semi-transmission filter shown in FIG. 12 according to a number of refractive layers included in the multi-layer semi-transmission filter.

In relation to FIG. 12, portions different from those of the above-described embodiment will be described to avoid redundancy.

First, referring to FIGS. 3 and 12, the display device shown in FIG. 3 may include a multi-layer semi-transmission filter MRF instead of the resonant filter DFPF. A light emitting element LD may include a light emitting structure EMT (see FIG. 3).

The multi-layer semi-transmission filter MRF may recycle light (e.g., blue light) which does not react with a color conversion layer CCL (see FIG. 3) to react with the color conversion layer CCL, using a refractive index difference.

The multi-layer semi-transmission filter MRF may be configured to reflect light in a specific wavelength band. The multi-layer semi-transmission filter MRF may reflect light in a first wavelength band, and transmit light in a second wavelength band different from the first wavelength band. In an embodiment, the multi-layer semi-transmission filter MRF may reflect blue light, and transmit green light and/or red light except the blue light.

The multi-layer semi-transmission filter MRF may include high refractive layers HRL1 to HRL4 and low refractive layers LRL1 to LRL4, which are alternately disposed. The high refractive layers HRL1 to HRL4 and the low refractive layers LRL1 to LRL4 may have different refractive indexes. The high refractive layers HRL1 to HRL4 and the low refractive layers LRL1 to LRL4, which are alternately disposed, may constitute a distributed Bragg reflective layer.

Each of the high refractive layers HRL1 to HRL4 may have a first refractive index, and each of the low refractive layers LRL1 to LRL4 may have a second refractive index smaller than the first refractive index. In an embodiment, each of the high refractive layers HRL1 to HRL4 may be configured as a transparent inorganic layer having the first refractive index of about 1.85, and each of the low refractive layers LRL1 to LRL4 may be configured as a transparent inorganic layer having the second refractive index of about 1.45. Each of the high refractive layers HRL1 to HRL4 may have a thickness of about 60 nm, and each of the low refractive layers LRL1 to LRL4 may have a thickness of about 60 nm. However, the disclosure is not limited thereto. Each of the high refractive layers HRL1 to HRL4 may include silicon nitride (SiNₓ), and each of the low refractive layers LRL1 to LRL4 may include silicon oxide (SiOₓ). However, the disclosure is not limited thereto.

In embodiments, the multi-layer semi-transmission filter MRF may include at least four pairs of refractive layers, and each of the refractive layers may include a high refractive layer and a low refractive layer disposed on the high refractive layer.

As shown in FIG. 12, the multi-layer semi-transmission filter MRF may include a first high refractive layer HRL1 and a first low refractive layer LRL1, a second high refractive layer HRL2 and a second low refractive layer LRL2, a third high refractive layer HRL3 and a third low refractive layer LR3, and a fourth high refractive layer HRL4 and a fourth low refractive layer LRL4, i.e., a total of four pairs of refractive layers, which are sequentially stacked.

As a refractive index difference is repeatedly formed in the multi-layer semi-transmission filter MRF, light may have different transmittances according to incident angles. The material included in each of the high refractive layers HRL1 to HRL4 and the low refractive layers LRL1 to LRL4, the thickness of each of the high refractive layers HRL1 to HRL4 and the low refractive layers LRL1 to LRL4, and/or the stacked number of each of the high refractive layers HRL1 to HRL4 and the low refractive layers LRL1 to LRL4 may be adjusted, so that the reflectance of light incident into the multi-layer semi-transmission filter MRF can be optimally increased. The thickness of each of the high refractive layers HRL1 to HRL4 and the low refractive layers LRL1 to LRL4 may be adjusted according to a wavelength of light and a refractive index.

Referring to FIG. 13, a first embodiment S2 is an embodiment including two pairs of refractive layers, a second embodiment S3 may be an embodiment including three pairs of refractive layers, a third embodiment S4 may be an embodiment including four pairs of refractive layers, a fourth embodiment S5 may be an embodiment including five pairs of refractive layers, and a fifth embodiment S6 may be an embodiment including six pairs of refractive layers. A reflectance is defined as a ratio of an amount of light reflected from the multi-layer semi-transmission filter MRF with respect to an amount of light incident into the multi-layer semi-transmission filter MRF, and is indicated as an arbitrary unit (a.u.).

A multi-layer semi-transmission filter MRF corresponding to the first embodiment S2 reflects less than 50% of blue-based light in a wavelength band of 420 nm to 480 nm, reflects 20% or more of green-based light in a wavelength band of 520 nm to 580 nm, and reflects less than 20% of red-based light in a wavelength band of 620 nm to 680 nm. A multi-layer semi-transmission filter MRF corresponding to the second embodiment S3 reflects 60% or more of the blue-based light, reflects less than 40% of the green-based light, and reflects less than 10% of the red-based light. A multi-layer semi-transmission filter MRF corresponding to the third embodiment S4 reflects 60% or more of the blue-based light, reflects less than 20% of the green-based light, and reflects less than 20% of the red-based light. A multi-layer semi-transmission filter MRF corresponding to the fourth embodiment S5 reflects 70% or more of the blue-based light, reflects less than 30% of the green-based light, and reflects less than 10% of the red-based light. A multi-layer semi-transmission filter MRF corresponding to the fifth embodiment S6 reflects 70% or more of the blue-based light, reflects less than 20% of the green-based light, and reflects less than 10% of the red-based light.

In case that the multi-layer semi-transmission filter MRF includes at least three pair of refractive layers, the multi-layer semi-transmission filter MRF may reflect 60% or more of the blue-based light. In case that the multi-layer semi-transmission filter MRF includes at least four pairs of refractive layers, the multi-layer semi-transmission filter MRF may reflect less than 20% of the green-based light. In case that the multi-layer semi-transmission filter MRF includes at least three pair of refractive layers, the multi-layer semi-transmission filter MRF may reflect less than 20% of the red-based light.

In case that the multi-layer semi-transmission filter MRF including at least four pairs of refractive layers is disposed between a light emitting element layer DPL (see FIG. 3) and a color filter layer CFL (see FIG. 3), a portion of the blue-based light incident into the multi-layer semi-transmission filter MRF without reacting with the color conversion layer CCL may be reflected to the color conversion layer CCL to be react with the color conversion layer, using a refractive index difference of the refractive layers. Accordingly, the recycling rate of blue light may be increased, thereby improving the light emission luminance of the color conversion layer CCL.

In the display device in accordance with the disclosure, a color conversion layer, a light emitting element layer, and a resonant filter may be sequentially disposed on a reflective layer. The resonant filter may reflect light in a first wavelength band (e.g., blue light), which is emitted from a first light emitting element layer, and may transmit light in a second wavelength band (i.e., light converted in the color conversion layer, e.g., red light and green light), which is emitted from the color conversion layer. Thus, the recycling rate of the light in the first wavelength band may be increased, and an amount of the light in the second wavelength band may be increased. Thus, light emission efficiency may be improved, and the reliability of the display device may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a reflective layer disposed on a substrate and reflecting light;
a color conversion layer disposed on the reflective layer, absorbing light in a first wavelength band, and emitting light in a second wavelength band;
a light emitting element layer disposed on the color conversion layer and emitting the light in the first wavelength band; and
a resonant filter disposed on the light emitting element layer, reflecting the light in the first wavelength band, and transmitting the light in the second wavelength band,
wherein the resonant filter includes a plurality of semi-transmission layers and at least one medium layer disposed between the plurality of semi-transmission layers.

2. The display device of claim 1, wherein
the resonant filter includes a first semi-transmission layer, a first medium layer, a second semi-transmission layer, a second medium layer, and a third semi-transmission layer, which are sequentially stacked,
the first semi-transmission layer, the second semi-transmission layer, and the third semi-transmission layer include a conductive material, and
the first medium layer and the second medium layer include an insulating material.

3. The display device of claim 2, wherein
the first semi-transmission layer, the second semi-transmission layer, and the third semi-transmission layer include a metal thin film having a thickness less than or equal to about 30 nm, and
the first medium layer and the second medium layer include an organic layer or an inorganic layer.

4. The display device of claim 2, wherein the first semi-transmission layer, the first medium layer, the second semi-transmission layer, the second medium layer, and the third semi-transmission layer have different thicknesses.

5. The display device of claim 2, wherein the first medium layer and the second medium layer have a same thickness.

6. The display device of claim 2, wherein
the first medium layer and the second medium layer have different thicknesses, and
one of the first medium layer and the second medium layer has a thickness which is less than two times of a thickness of another one of the first medium layer and the second medium layer.

7. The display device of claim 2, wherein
the light emitting element layer includes an anode electrode and a light emitting layer,
the first semi-transmission layer is a cathode electrode,
the first medium layer is a capping layer, and
the second semi-transmission layer, the second medium layer, and the third semi-transmission layer are an encapsulation layer.

8. The display device of claim 7, wherein the resonant filter has a double Fabry-Perot cavity structure.

9. The display device of claim 7, wherein the anode electrode includes a transparent conductive material.

10. The display device of claim 7, wherein the anode electrode is connected to the reflective layer while penetrating the color conversion layer.

11. The display device of claim 1, wherein
the reflective layer, the color conversion layer, and the light emitting element layer constitute a pixel,
the pixel includes a first sub-pixel, a second sub-pixel, and a third sub-pixel, and
the resonant filter is disposed in the first sub-pixel and the second sub-pixel, and is not disposed in the third sub-pixel.

12. The display device of claim 11, wherein
the first sub-pixel emits red light in a wavelength band in a range of about 620 nm to about 680 nm,
the second sub-pixel emits green light in a wavelength band in a range of about 520 nm to about 580 nm, and
the third sub-pixel emits blue light in a wavelength band in a range of about 420 nm to about 480 nm.

13. The display device of claim 12, wherein
the resonant filter reflects about 70% to about 90% of the blue light, and
the resonant filter transmits about 40% to about 90% of the red light and the green light.

14. The display device of claim 12, wherein
the light emitting element layer emits the blue light or celadon light obtained by mixing blue and green, and
the color conversion layer includes:
first color conversion particles disposed in the first sub-pixel, absorbing the blue light, and emitting the red light; and
second color conversion particles disposed in the second sub-pixel, absorbing the blue light, and emitting the green light.

15. The display device of claim 14, wherein the color conversion layer further includes light scattering particles disposed in the third sub-pixel.

16. The display device of claim 14, further comprising:
a color filter layer disposed on the resonant filter,
wherein the color filter layer includes:
a first color filter disposed in the first sub-pixel;
a second color filter disposed in the second sub-pixel; and
a third color filter disposed in the third sub-pixel.

17. The display device of claim 1, wherein
the resonant filter includes a first semi-transmission layer, a first medium layer, a second semi-transmission layer, a second medium layer, a third semi-transmission layer, and a third medium layer, which are sequentially stacked,
the first semi-transmission layer, the second semi-transmission layer, and the third semi-transmission layer include a conductive material, and
the first medium layer, the second medium layer, and the third medium layer include an insulating material.

18. The display device of claim 17, wherein
the light emitting element layer includes an anode electrode and a light emitting layer,
the first semi-transmission layer is a cathode electrode,
the first medium layer and the third medium layer include an inorganic material, and the second medium layer includes an organic material, and
the first medium layer, the second medium layer, and the third medium layer are an encapsulation layer.

19. A display device comprising:
a reflective layer disposed on a substrate and reflecting light;
a color conversion layer disposed on the reflective layer, absorbing light in a first wavelength band, and emitting light in a second wavelength band;
a light emitting element layer disposed on the color conversion layer and emitting the light in the first wavelength band; and
a multi-layer semi-transmission filter disposed on the light emitting element layer, reflecting the light in the first wavelength band, and transmitting the light in the second wavelength band, wherein
the multi-layer semi-transmission filter includes at least four pairs of refractive layers, and
each of the refractive layers includes a high refractive layer and a low refractive layer, which are sequentially stacked.

20. The display device of claim 19, wherein
the high refractive layer has a thickness of about 60 nm and a refractive index of about 1.85, and
the low refractive layer has a thickness of about 60 nm and a refractive index of about 1.45.
